(19) United States
(12) Patent Application Publication
(10) Pub. No.: US 2016/0021755 A1
(43) Pub. Date: Jan. 21, 2016

(54) CHIP EMBEDDED SUBSTRATE AND METHOD OF MANUFACTURING THE SAME

(71) Applicant: Samsung Electro-Mechanics Co., Ltd., Suwon-si (KR)

(72) Inventors: Jung Han LEE, Seoul (KR); Tae Hong MIN, Suwon-si (KR); Yul Kyo CHUNG, Yongin-si (KR); Young Gwan KO, Seoul (KR); Myung Sam KANG, Hwaseong-si (KR)

(73) Assignee: Samsung Electro-Mechanics Co., Ltd., Suwon-si (KR)

(21) Appl. No.: 14/801,076

(22) Filed: Jul. 16, 2015

(30) Foreign Application Priority Data
Jul. 16, 2014 (KR) 10-2014-0089884

(51) Int. Cl. H05K 1/18; H05K 3/40; H05K 3/46; H05K 1/11; H05K 3/30

(52) U.S. Cl. CPC H05K 1/185; H05K 1/11; H05K 3/30; H05K 3/4644; H05K 3/40; H05K 2201/10015; H05K 2201/09209

(57) ABSTRACT

The present invention relates to a chip embedded substrate, which includes a substrate formed by alternately stacking an insulation layer and a circuit layer and an embedded chip equipped with a connection terminal and mounted inside the substrate, wherein the connection terminal is protruded from the insulation layer placed on the outermost layer of the substrate, and a connection surface to be connected to an electronic component is exposed to the outside.

### CROSS-REFERENCE TO RELATED APPLICATIONS

Claim and incorporate by reference domestic priority application and foreign priority application as follows:

“CROSS REFERENCE TO RELATED APPLICATION

This application claims the benefit under 35 U.S.C. Section 119 of Korean Patent Application Serial No. 10-2014-0089884, entitled filed Jul. 16, 2014, which is hereby incorporated by reference in its entirety into this application.”

### BACKGROUND OF THE INVENTION

1. Field of the Invention

The present invention relates to a substrate; and, more particularly to a chip embedded substrate and a method for manufacturing the same.

2. Description of the Related Art

In recent, due to miniaturization, slimming, and light weight of electronic devices, there is a need for miniaturization and light weight of printed circuit boards (PCB) used in the electronic devices. For the printed circuit boards for packages, the usage of embedding substrates, which embeds active elements such as an IC (integrated circuit) as well as passive elements such as a condenser inside the printed circuit board, has been gradually increased.

When a chip is embedded inside the substrate, the size of the electronic component decreases thus helps to minimize and lighten the products. Also, the operating frequency of the circuit can be increased since parasitic components can be removed. Furthermore, due to the explosive growth of the market of portable electronic devices, chip embedded substrates, which can satisfy the needs for a lighter and smaller products, are being popularly recognized.

Meanwhile, the substrate is equipped with high-heating devices such as power devices or LEDs on its surface. If the heat generated from these high-heating devices may not be discharged quickly, the heat rises the temperature of the substrate resulting in malfunction, whereby the substrates excellent in dissipating heat are demanded.

Therefore, in the chip embedded substrate, it is very important to have a connection structure between the chip mounted inside the substrate and the heating device equipped in the surface of the substrate in a proper form of releasing heat. Otherwise, the heat generated from the heating device does not penetrate to the outside and it is concentrated between the heating device and the embedded chip, whereby the temperature of the whole substrate rises.

Viewing the prior reference (Japanese Patent Publication No. 2013-247353) related to the chip embedded substrate, the embedded chip mounted inside of the substrate and the heating device (the surface mounting element) mounted on the surface of the substrate are electrically connected through the connection path connecting to the via, the pad and the solder ball (the solder bump).

Thus, if a lot of elements are arranged between the embedded chip and the heating device, the heating movement does not perform smoothly and the reliability of products is deteriorated.

### SUMMARY OF THE INVENTION

The present invention has been invented to minimize the number of elements equipped between the embedded chip mounted inside the substrate and the heating device placed on the surface of the substrate in order to provide a chip embedded substrate that quickly discharges the heat therebetween.

To achieve the object mentioned above, the present invention provides a chip embedded substrate which allows a connection between an electronic component equipped on the surface of the substrate and an embedded chip mounted inside the substrate without passing through a via to quickly transfer heat.

For this, in the chip embedded substrate of the present invention, the thickness of the connection terminal which connects to the electronic component is thicker than a conventional chip well known in the art to protrude from an insulation layer placed on the outermost layer of the substrate, whereby a connection surface to be connected with the electronic component is exposed to the outside.

Also, for the material of the insulation layer mounted with the embedded chip in the present invention, metals such as Aluminum or Copper which is excellent in heat conductivity is used to effectively release the heat to the side and the bottom of the substrate.

For a method to manufacture a chip embedded substrate of this structure, the present invention is provided with a method of stacking a build-up insulation layer to the same height or lower than the connection terminal when stacking the build-up insulation layer in a core insulation layer mounted with the embedded chip.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a chip embedded substrate in accordance with one embodiment of the present invention;

FIG. 2 is a drawing describing a moving path of heat in the chip embedded substrate of the present invention;

FIG. 3 is a cross-sectional view of the chip embedded substrate in accordance with another embodiment of the present invention;

FIG. 4 is a cross-sectional view of the chip embedded substrate in accordance with still another embodiment of the present invention;

FIG. 5 is a process flowchart showing a method for manufacturing a chip embedded substrate in accordance with the present invention; and

FIG. 6 to FIG. 10 are cross-sectional views showing each process of FIG. 5, FIG. 6 is a cross-sectional view showing a process of forming a circuit layer, FIG. 7 is a cross-sectional view showing a process of mounting an embedded chip, FIG. 8 is a cross-sectional view showing a process of forming a build-up insulation layer, FIG. 9 is a cross-sectional view showing a process of forming a solder resist layer and FIG. 10 is a cross-sectional view showing a process of mounting an electronic component.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Hereinafter, configurations and operational effects of the present invention will be described in detail with reference to the accompanying drawings.

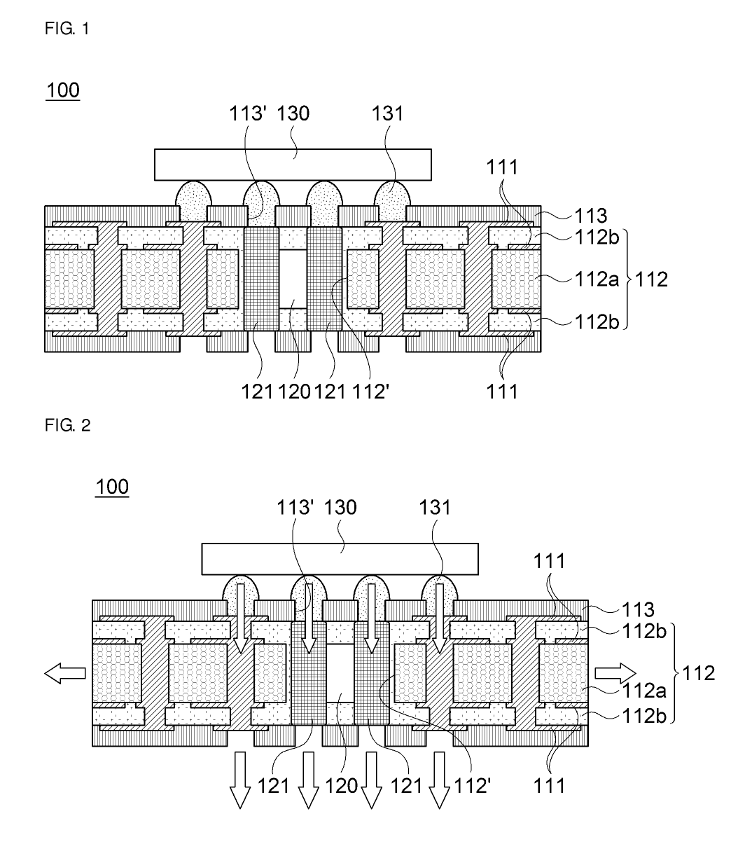

FIG. 1 is a cross-sectional view of a chip embedded substrate in accordance with the present invention. For reference, elements in the drawing figures are not necessarily drawn to scale. For example, the dimensions of some of the elements in the figures may be exaggerated relative to other elements to help improve understanding of embodiments of the present invention.

Referring to FIG. 1, the chip embedded substrate 100 of the present invention includes a substrate 110 formed by alternately stacking a circuit layer 111 and an insulation layer 112, an embedded chip 120 mounted inside the substrate 110 and an electronic component 130 loaded on a surface of the substrate 110.

The circuit layer 111 can be classified depending on its purpose, for example, a ground wiring forming a grounded area, a power wiring to supply power and a signal wiring to perform a signal transfer function, and electric contacts of each surface can be realized through via. In the embodiment of the present invention, a multi-layer substrate consisted of four layers of the circuit board 111 is shown as an example, but it is not limited thereto. The number of layers of the circuit layer 111 may be increased or decreased depending on the design.

The insulation layer 112 protects the circuit layer 111 and insulates each layer; and the insulation layer 112 is classified into a core insulation layer 112a, where the embedded chip 120 is mounted, and a pair of build-up insulation layers 112b to stack on a top and a bottom of the core insulation layer 112a.

The material of the insulation layer 112 may be a thermosetting plastic such as an epoxy or a thermoplastic such as a Polyimide, and a prepreg of those plastic impregnated with reinforcements such as fiber glass or an inorganic filler. Especially, for the core insulation layer 112a, a metal core excellent in heat conductivity such as aluminum or copper is suitable since heat generated from the electronic component 130 is delivered through the embedded chip 120.

The embedded chip 120 is mounted inside an opening 112′ which is penetrated through the core insulation layer 112a, here the embedded chip 120 can be a Multi-Layered Ceramic Capacitor (MLCC) formed by alternately stacking conduction films and ceramic sheets. Furthermore, active elements such as X-tal, or an RF chip or passive elements like resistors or inductors can be appropriately selected for the embedded chip 120. In addition, in the embodiment of the present invention, although it is shown with only one embedded chip 120 mounted, but, this is only an embodiment of the present invention and the number is not limited thereto.

In the embedded chip 120, the connection terminal 121 is formed as an external electrode to be electrically conducted to the outside. That is, the conductive layer inside of the embedded chip 120 is in contact with the connection terminal 121 by being exposed to the outside of the body of the embedded chip and a specific surface of the connection terminal 121 is connected to the electric element 130. Through this, the embedded chip 120 is electrically connected to the electronic element 130. Herein, the specific surface of the connection terminal 121 to be connected to the electronic element 130 is referred to as ‘a connection surface’.

The connection terminal 121 is protruded at the build-up insulation layer 112b positioned at the outmost layer of the substrate 110 and the connection surface of the connection terminal 121 is exposed to the outside. Accordingly, the height of the connection terminal 121 is formed at the same height of the build-up insulation layer 112b as shown in FIG. 1.

In case when the embedded chip 120 is MLCC, since the connection terminal 121 body is generally formed on both side surfaces of the chip body, the thickness of the connection terminal 121 is formed larger than that of the core insulation layer 112a. Accordingly, the connection terminal 121 is protruded to both of the top side build-up insulation layer 112b and the bottom side build-up insulation layer 112b. And, the top connection surface of the connection terminal 121 is formed at the same height of the top side build-up insulation layer 112b to be exposed to the outside, and the bottom connection surface of the connection terminal 121 is formed at the same height of the bottom side build-up insulation layer 112b to be exposed to the outside.

Like this, the embedded chip 120 used in the present invention, increases the thickness of the connection terminal 121 in comparison with a conventional chip; and, accordingly, it can be connected to the electronic element 130 without passing through an additional via in the middle thereof different from a conventional chip embedded substrate. In this result, the signal transfer characteristics are improved by shortening the electrical connection path between the electronic element 130 and the embedded chip 120.

The solder resist layer 110 is stacked on a top of a build-up insulation layer 112b placed on an outermost layer of the substrate 110. The solder resist 113 is formed of a photo-sensitive resin composition as a layer to protect the outermost layer of the substrate 111 from contamination of foreign materials.

On the solder resist layer 113, a cavity 113′ to expose the connection surface of a connection terminal 121 is formed and a solder ball 131 is formed in the cavity 113′. Also, a bottom surface of the electronic component 130 is bonded to the solder ball 131 to be mounted on a surface of the substrate 110. Accordingly, since only the solder ball 131 exists between the electronic component and the embedded chip, in this result, the heat generated from the electronic component 130 is rapidly transferred to the connection terminal 121.

FIG. 2 is a drawing to describe a moving path of heat in the chip embedded substrate 100 in accordance with the present invention, wherein the arrows indicate the flow of heat.

Referring to FIG. 2, the heat generated from the electronic component 130 is transferred to the connection terminal 121 directly through the solder ball 131, the transferred heat is then smoothly discharged to the side and the bottom of the substrate 110 through the core insulation layer 112a made of a metal material with excellent conductivity.

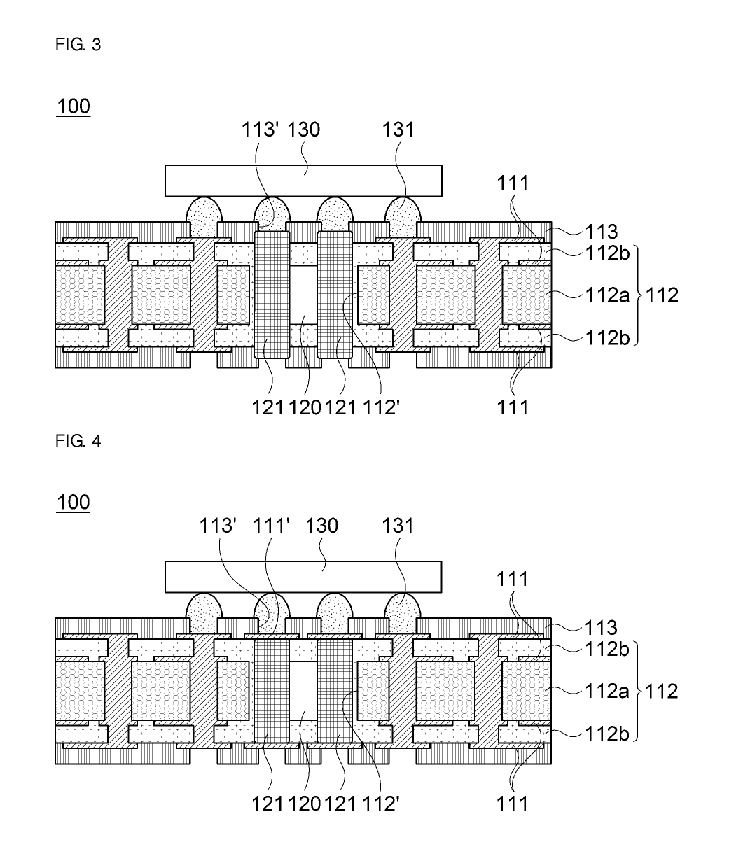

FIG. 3 is a cross-sectional view of the chip embedded substrate 100 in accordance with a secondary embodiment of the present invention.

Referring to FIG. 3, in the embodiment, the height of the connection terminal 121 is formed higher than the build-up insulation layer 112b placed on the outermost of the substrate 110. Therefore, in case when the embedded chip 120 is an MLCC, the connection terminals 121 attached on each side of the chip body are thicker than the total thickness of the core insulation layer 112a and the build-up insulation layer 112b.

Here, the connection terminal 121 which penetrates the build-up insulation layer 112b and protrudes to the outside is covered with the solder resist layer 113. The connection surface to be connected with the electronic component is exposed through the cavity 113′ formed on the solder resist layer 113 to the outside, thereby being connected with the solder ball 131. Since the other compositions are identical to FIG. 1 described above, the detailed descriptions thereof will be omitted.

FIG. 4 is a cross-sectional view of the chip embedded substrate 100 in accordance with a third embodiment of the present invention.

Referring to FIG. 4, a pad 111′ is further formed between the connection layer 121 and the solder ball 131.

The pad 111′ is formed with the circuit layer 112 on the top of the build-up insulation layer 112b placed on the outermost layer of the substrate 110 together and has an area larger than the horizontal cross-section area of the connection terminal 121. Thus, this improves the reliability of the connection between the solder ball 131 and the connection terminal 121 by increasing the area to be connected with the solder ball 131.

Hereinafter, the method for manufacturing the chip embedded substrate 100 of the present invention will be explained.

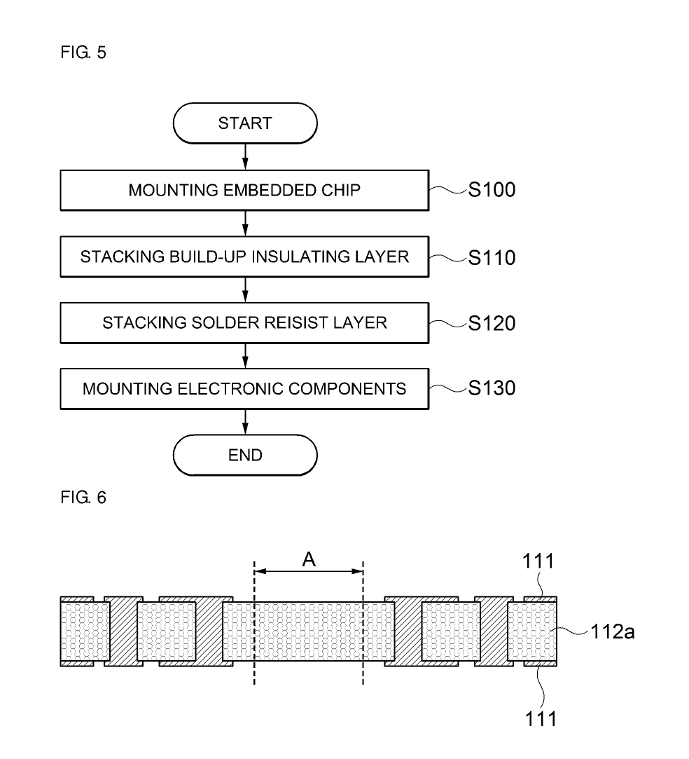

FIG. 5 is a process flowchart showing a method for manufacturing a chip embedded substrate 100 in accordance with the present invention and FIG. 6 to FIG. 10 are cross-sectional views showing each process.

Referring to FIG. 5 to FIG. 10, the method for manufacturing a chip embedded substrate 100 is processed by first, mounting an embedded chip 120 in a core insulation layer 112a which a circuit layer 111 is formed on a single surface or double surfaces (S100).

The circuit layer 111 is formed outside on a part except an area A where the embedded chip 120 is to be mounted, and it may be formed by using an ordinary pattern process well known in the art such as SAP (Semi-Additive Process), MSAP (Modified Semi-Additive Process), or Subtractive process (FIG. 6).

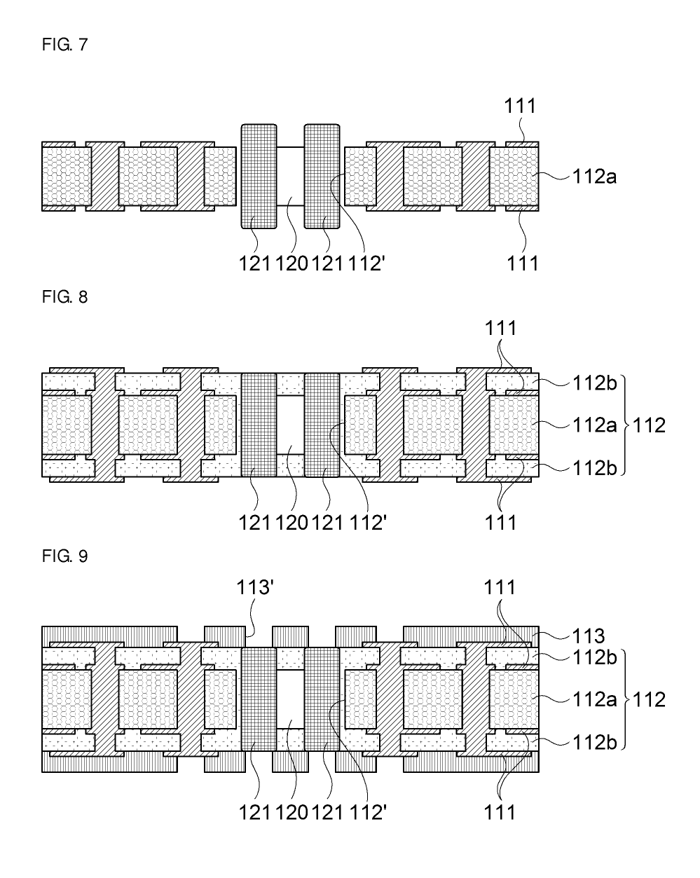

When the circuit layer 111 is formed, an opening 112′ is processed on the area (A) where the embedded chip is to be mounted by using a laser or mechanical methods such as router or punching. The embedded chip 120 is then mounted inside the opening 112′ (FIG. 7). Although not showing in detail, the fixing of the embedded chip 120 in the opening 112′ can employ various methods such as attaching an adhesive tape between the embedded chip 120 and the inner wall of the opening 112′ or filling a resin composition of the same substance as the build-up insulation layer 112b.

The embedded chip 120 used in the present invention has a thicker connection terminal 121 than a conventional chip, and if MLCC is used for the embedded chip 120, the thickness of the connection terminal 121 placed on both of the chip body is thicker than the core insulation layer 112a, thus the embedded chip 120 is mounted in such a way that the connection terminal 121 is protruded to the outside.

Thereafter, a step of stacking a build-up insulation layer 112b on the core insulation layer 112a is performed (S110).

The build-up insulation layer 112b is stacked in such a way that all of the circuit layers 111 formed on the core insulation layer 112a are covered, and it is stacked to expose the connection surface of the connection terminal 121 to the outside. Accordingly, the build-up insulation layer 112b may be stacked at the same height of the connection terminal 121 (FIG. 8). Or, the build-up insulation layer 112b can be stacked at the thickness of the height lower than the connection terminal 121, in this case, becomes the structure as shown in FIG. 3.

If the build-up insulation layer 112b is stacked, the circuit layer 111 can be formed on the top of the build-up insulation layer 112b by using SAP (Semi-Additive Process), MSAP (Modified Semi-Additive Process) or a subtractive process or the like. At this time, the pad 111′ joined to the connection terminal 121 can be formed together, in this case, becomes the structure as shown in FIG. 4. Of course, if the connection with the solder ball 131 can be secured only the connection terminal 121, the formation of the pad 111′ can be omitted.

Next, a step of stacking a solder resist layer 113 formed of a photo-sensitive resin composition on a top surface of the build-up insulation layer 112b is performed (S120).

The solder resist layer 113 can be stacked by coating with a liquid-type or laminating a dry resin film. After, a mask is attached on the top surface of the solder resist layer and exposed to light. A portion unhardened by the light is developed to form a cavity 113′ to expose a connection surface of the connection layer 121 to the outside (FIG. 9).

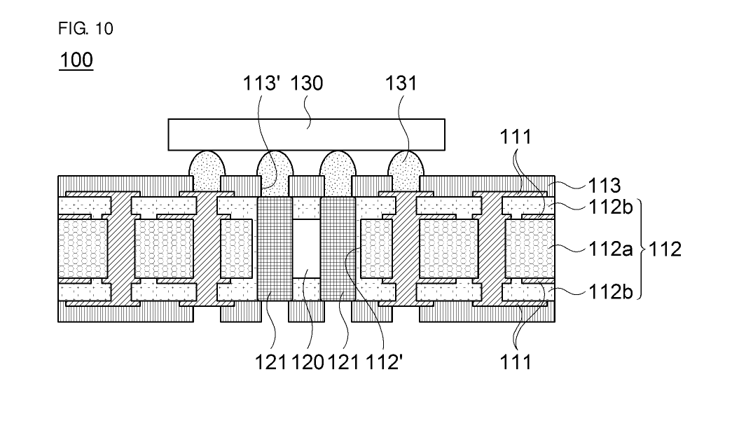

Last, a solder ball 131 is formed by filling the cavity 113′ with conductive paste and an electronic component 130 is mounted on a surface of a substrate 110 to be bonded, thereby finally finishing the chip embedded substrate of the present invention (S130, FIG. 10).

In accordance with the present invention, the overall heat discharge characteristics of the substrate can be improved by rapidly transferring the heat generated in the electronic elements mounted on the surface of the substrate to the embedded chip mounted inside of the substrate.

And also, the signal transfer characteristics can be improved by allowing the electronic element and the embedded chip to be directly connected to the solder ball without passing through the via.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A chip embedded substrate comprising:
a substrate formed by alternately stacking an insulation layer and a circuit layer; and
an embedded chip equipped with a connection terminal and mounted inside the substrate;
wherein the connection terminal is protruded from the insulation layer placed on the outermost layer of the substrate, and a connection surface connected to an electronic component is exposed to the outside thereof

2. The chip embedded substrate according to claim 1, wherein a height of the connection terminal is higher than the insulation layer placed on an outermost layer of the substrate.

3. The chip embedded substrate according to claim 1, wherein a thickness of the connection terminal is equal to or thicker than the insulation layer mounted with the embedded chip.

4. The chip embedded substrate according to claim 1, wherein the embedded chip may be a Multi-Layered Ceramic Capacitor (MLCC).

5. The chip embedded substrate according to claim 4, wherein the connection terminal is equipped on both sides of the embedded chip.

6. The chip embedded substrate according to claim 1, wherein the insulation layer mounted thereon the embedded chip is a metal core.

7. The chip embedded substrate according to claim 1, further comprises:
a solder resist layer stacked on a top surface of the insulation layer which is placed on the outermost layer of the substrate and provided with a cavity to expose a connection surface of the connection terminal.

8. The chip embedded substrate according to claim 7, further comprises:
a solder ball equipped inside the cavity; and
an electronic component mounted on a surface of the substrate by being bonded on the solder ball;

9. The chip embedded substrate according to claim 8, further comprises a pad equipped between the connection terminal and the solder ball.

10. A method of manufacturing a chip embedded substrate comprising:
mounting an embedded chip inside a core insulation layer on which a circuit layer is formed on one or both surfaces, wherein a connection terminal of the embedded chip is protruded outwards; and
stacking a build-up insulation layer on the core insulation layer, wherein a connection surface of the connection terminal is exposed to the outside.

11. The method for manufacturing the chip embedded substrate according to claim 10, wherein the build-up insulation layer is stacked to the same height as the connection terminal or stacked lower than the connection terminal.

12. The method for manufacturing the chip embedded substrate according to claim 10, after stacking the build-up insulation layer, further comprises:
stacking a solder resist layer formed with a cavity to expose the connection surface of the connection terminal on a top of the build-up insulation layer.

13. The method for manufacturing the chip embedded substrate according to claim 12, further comprises:
forming a solder ball on the cavity and mounting an electronic component of the surface of the substrate.

14. The method for manufacturing the chip embedded substrate according to claim 12, before stacking the solder resist layer, further comprises:
forming a pad to be connected with the connection terminal on the surface of the build-up insulation layer before stacking the solder resist layer.
